(19) United States
(12) Patent Application Publication
(10) Pub. No.: US 2026/0107699 A1
(43) Pub. Date: Apr. 16, 2026

(54) PHASE CHANGE MATERIAL DEVICE USING A SIDEWALL LINER AND METHODS FOR FORMING THE SAME

(71) Applicant: Taiwan Semiconductor Manufacturing Company Limited, Hsinchu (TW)

(72) Inventors: Kuo-Pin Chang, Zhubei City (TW); Chang-Chih Huang, Taichung (TW); Yu-Wei Ting, Taipei City (TW); Kuo-Ching Huang, Hsinchu City (TW); Hung-Ju Li, Hsinchu City (TW)

(21) Appl. No.: 19/044,672

(22) Filed: Feb. 4, 2025

Related U.S. Application Data
(60) Provisional application No. 63/707,224, filed on Oct. 15, 2024.

(51) Int. Cl. H10N 70/20; H10B 63/00; H10B 63/10; H10N 70/00

(52) U.S. Cl. CPC H10N 70/231; H10B 63/10; H10B 63/30; H10N 70/023; H10N 70/063; H10N 70/253; H10N 70/841; H10N 70/8613; H10N 70/883; H10N 70/8845; H10N 70/026

(57) ABSTRACT

A device structure may be provided by forming a bottom electrode and a heater element within a dielectric material layer; depositing and patterning a continuous layer stack including a bottom liner layer, a phase change material layer including a phase change material, and a top electrode material layer; and forming at least one sidewall liner by depositing and patterning a sidewall liner material. At least one sidewall liner is formed on at least one sidewall of a patterned portion of the continuous layer stack.

The at least one sidewall liner includes a material having an electrical conductivity that is higher than an electrical conductivity of an amorphous phase of the phase change material.

### RELATED APPLICATIONS

This application claims the benefit of priority to U.S. Provisional Application No. 63/707,224, entitled “Phase-Change Memory with Vertical Liner,” filed on Oct. 15, 2024, the entire contents of which are incorporated by reference herein for all purposes.

### BACKGROUND

Phase change material (PCM) devices may be used for memory-based computing applications due to their scalability and non-volatility. However, PCM devices are known to suffer from resistance drift, particularly in the high-resistance state (HRS), which may adversely affect computing accuracy. Successful implementation of the PCM devices for high performance computing such as computation-in-memory (CIM) requires enhanced reliability of the high resistance states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. The dimensions of the various features may be arbitrarily increased or reduced for clarity of discussion.

FIG. 1 is a vertical cross-sectional view of an intermediate embodiment structure after formation of field effect transistors, metal interconnect structures, and dielectric material layers according to an embodiment of the present disclosure.

FIG. 2 is a vertical cross-sectional view of the intermediate embodiment structure after formation of via cavities through a dielectric material layer according to an embodiment of the present disclosure.

FIG. 3 is a vertical cross-sectional view of the intermediate embodiment structure after formation of metal via structures according to an embodiment of the present disclosure.

FIG. 4 is a vertical cross-sectional view of the intermediate embodiment structure after formation of bottom electrodes and heater cavities according to an embodiment of the present disclosure.

FIG. 5 is a vertical cross-sectional view of the intermediate embodiment structure after lateral expansion of heater cavities according to an embodiment of the present disclosure.

FIG. 6 is a vertical cross-sectional view of the intermediate embodiment structure after formation of heater elements according to an embodiment of the present disclosure.

FIG. 7 is a vertical cross-sectional view of the intermediate embodiment structure after formation of a continuous layer stack including a bottom liner layer, a phase change material layer comprising a phase change material, and a top electrode material layer according to an embodiment of the present disclosure.

FIG. 8 is a vertical cross-sectional view of the intermediate embodiment structure after patterning the continuous layer stack into in-process layer stacks each including an in-process bottom liner, an in-process phase change material portion, and an in-process top electrode according to an embodiment of the present disclosure.

FIG. 9 is a vertical cross-sectional view of the intermediate embodiment structure after formation of a sidewall liner layer according to an embodiment of the present disclosure.

FIG. 10 is a vertical cross-sectional view of the intermediate embodiment structure after formation of in-process sidewall liners according to an embodiment of the present disclosure.

FIG. 11 is a vertical cross-sectional view of the intermediate embodiment structure after patterning the in-process layer stacks into layer stacks each including a bottom liner, a phase change material portion, and a top electrode and patterning the in-process sidewall liners into sidewall liners according to an embodiment of the present disclosure.

FIG. 12 is a vertical cross-sectional view of the embodiment structure after removal of a patterned etch mask layer according to an embodiment of the present disclosure.

FIGS. 13A-13C illustrate sequential top-down views of a region of a first configuration of the embodiment structure during the processing steps of FIGS. 10-12.

FIGS. 14A-14C illustrate sequential top-down views of a region of a second configuration of the embodiment structure during the processing steps of FIGS. 10-12.

FIGS. 15A-15C illustrate sequential top-down views of a region of a third configuration of the embodiment structure during the processing steps of FIGS. 10-12.

FIG. 16 illustrates a top-down view of a region of a fourth configuration of the embodiment structure after the processing steps of FIG. 10.

FIG. 17 is a vertical cross-sectional view of the embodiment structure after formation of an encapsulation dielectric layer and additional metal interconnect structures according to an embodiment of the present disclosure.

FIGS. 18A-18D are various configurations of a phase change material portion in various programmed resistance states according to an embodiment of the present disclosure.

FIG. 19 is a vertical cross-sectional view of a first alternative configuration of the embodiment structure after formation of heater elements according to an embodiment of the present disclosure.

FIG. 20 is a vertical cross-sectional view of the first alternative configuration of the embodiment structure after formation of the encapsulation dielectric layer and the additional metal interconnect structures according to an embodiment of the present disclosure.

FIG. 21 is a vertical cross-sectional view of a second alternative configuration of the embodiment structure after formation of heater elements according to an embodiment of the present disclosure.

FIG. 22 is a vertical cross-sectional view of the second alternative configuration of the embodiment structure after formation of the encapsulation dielectric layer and the additional metal interconnect structures according to an embodiment of the present disclosure.

FIG. 23 is a flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Phase change memory (PCM) devices may be used to store weights in computation-in-memory (CIM) applications. Achieving high efficiency and low power in CIM depends on the accuracy of weights. In other words, the programmed resistance of PCM memory cells needs to reproduce target resistance with high reliability. The resistance of high resistance states may be prone to variations. Further, both the low-resistance state (LRS) and the high-resistance state (HRS) exhibit resistance drift. The resistance drift varies with the number of program cycles, and may lead to unstable weights and an increased error rate in CIM computations. Furthermore, related PCM designs, in which the HRS resistance is dominated by a mushroom-shaped amorphous region, often suffer from inherent limitations such as large cell sizes, narrow memory windows, and high write power requirements. These inherent limitations may undermine the efficiency, scalability, and accuracy of PCM for modern CIM applications.

Various embodiments of the present disclosure may provide a phase change memory cell using at least one sidewall liner. Each sidewall liner may be formed on a sidewall of a phase change material portion, and may control the resistance of the high resistance state. Further, the phase change material portion may be programmed to form different volumes for the amorphous volume of the phase change material portion. In such an embodiment, the phase change material portion may be programmed into three or more different states having different resistance values, thereby providing a configuration that is conducive to CIM operations. In addition, a bottom liner may be provided underneath the phase change material portion and over a heater element.

The overall resistance of the phase change memory cell may be determined by the surface area of the combination of the bottom liner and the sidewall liner that is separated from a crystalline volume of the phase change memory cell, i.e., by the surface area of the combination of the bottom liner and the sidewall liner that contacts an amorphous volume of the phase change memory cell. Since the overall resistance of the phase change memory cell may be determined by the resistance of the segments of the bottom liner and the sidewall liner that contacts the amorphous volume of the phase change memory cell, resistance drift in the phase change memory cells may be reduced to a insubstantial level, and weights in CIM applications, as manifested by the resistance of the phase change memory cell, may be stabilized.

A resistance range of the phase change memory cells may be expanded by increasing the resistivity of the material of the sidewall liner relative to the resistivity of the material of the bottom liner, which may be affected by incorporating nitrogen atoms or carbon atoms into the metallic material of the sidewall liner. Embodiments of the present disclosure may provide reduced power consumption, smaller cell sizes, and improved reliability for accurate computations. By suppressing the effect of resistance drift, the phase change memory cells of the present disclosure may enhance performance, reliability, and efficiency in CIM applications. The various embodiments of the present disclosure are now described with reference to accompanying drawings.

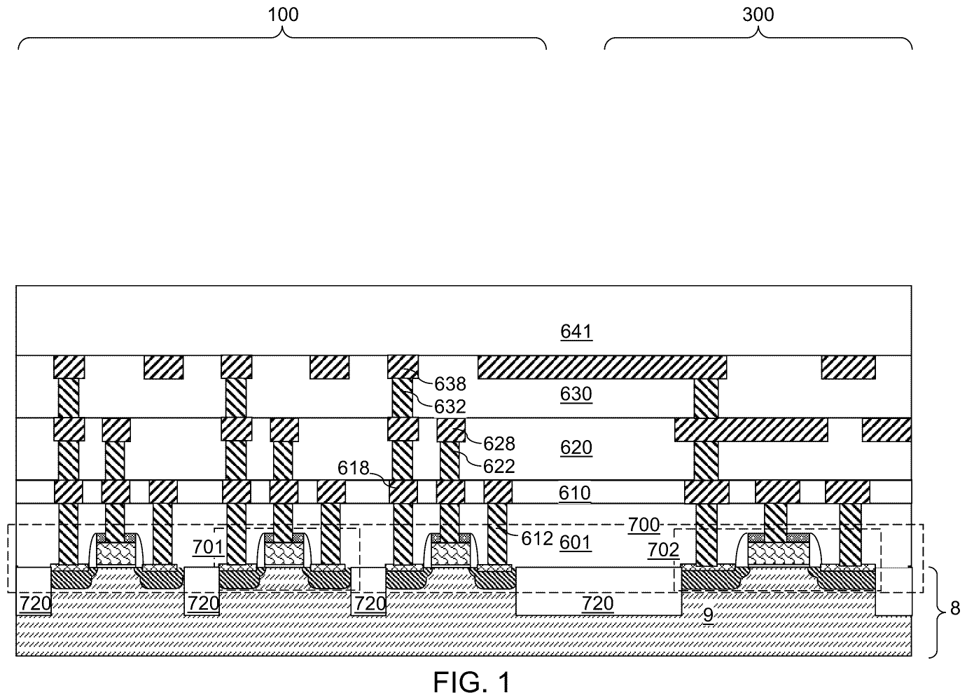

Referring to FIG. 1, an intermediate embodiment structure according to the present disclosure is illustrated. The intermediate embodiment structure includes a substrate 8, which may be a semiconductor substrate, such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720.

Semiconductor devices 700 may be formed on the semiconductor material layer 9. The semiconductor devices 700 may comprise complementary metal-oxide-semiconductor (CMOS) transistors and optionally additional semiconductor devices (such as resistors, diodes, capacitor structures, etc.). The semiconductor devices 700 may comprise programming transistors 701 that are formed in a memory array region 100, and peripheral transistors 702 that are formed in a peripheral region 300. Each field effect transistor (701, 702) may comprise a source region, a drain region, a channel region, a gate dielectric, and a gate electrode. In one embodiment, the channel region may comprise a portion of the semiconductor material layer 9, and may comprise a single crystalline semiconductor material. Each of the programming transistors 701 may be configured to provide a set of programming pulses for a respective phase change memory cell to be subsequently formed. The peripheral transistors 702 may be formed as components of a peripheral circuit that controls the operation of the programing transistors 701, and interfaces with an input/output (I/O) circuit (not illustrated).

In one embodiment, the substrate 8 may include a single crystalline silicon substrate, and the field effect transistors (701, 702) may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures may be formed within dielectric material layers may be subsequently formed over the substrate 8 and the semiconductor devices. In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the semiconductor devices 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. An additional dielectric material layer, which is herein referred to as a lower fourth interconnect-level dielectric material layer 641 may be formed over the third interconnect-level dielectric material layer 630.

Each of the dielectric material layers (601, 610, 620, 630, 641) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure.

Generally, semiconductor devices (such as field effect transistors (701, 702)) may be formed on a substrate 8, and metal interconnect structures (612, 618, 622, 628, 632, 638) and dielectric material layers (601, 610, 620, 630, 641) over the semiconductor devices. The metal interconnect structures (612, 618, 622, 628, 632, 638) may be formed in the dielectric material layers (601, 610, 620, 630, 641), and may be electrically connected to the semiconductor devices.

In summary, programming transistors 701 may be formed on a substrate 8. Metal interconnect structures (612, 618, 622, 628, 632, 638) formed within interconnect-level dielectric material layers (601, 610, 620, 630, 641) may be formed over the programming transistors 701. The metal interconnect structures (612, 618, 622, 628, 632, 638) may be configured to be electrically connected to heater elements of phase change memory cells to be subsequently formed.

According to an aspect of the present disclosure, the programming transistors 701 may be configured to program a respective one of the phase change memory cells into at least two different resistive states, and preferably into at least three different resistive states, and more preferably into at least four different resistive states. The programming of each phase change memory cell into different resistive states may be effected by selecting a pulse pattern from a set of pre-programmed pulse patterns that each programming transistor 701 may apply. The pulse patterns may differ from one another by the duration of a pulse pattern and the peak voltage of the pulse pattern. In one embodiment, the total number of resistive states that a phase change memory cell may be programmed into may be in a range from 2 to 64, such as from 3 to 16, and/or from 4 to 8, although a greater number of resistive states may be programmed as needed by altering the pulse pattern that is generated from each programming transistor 701.

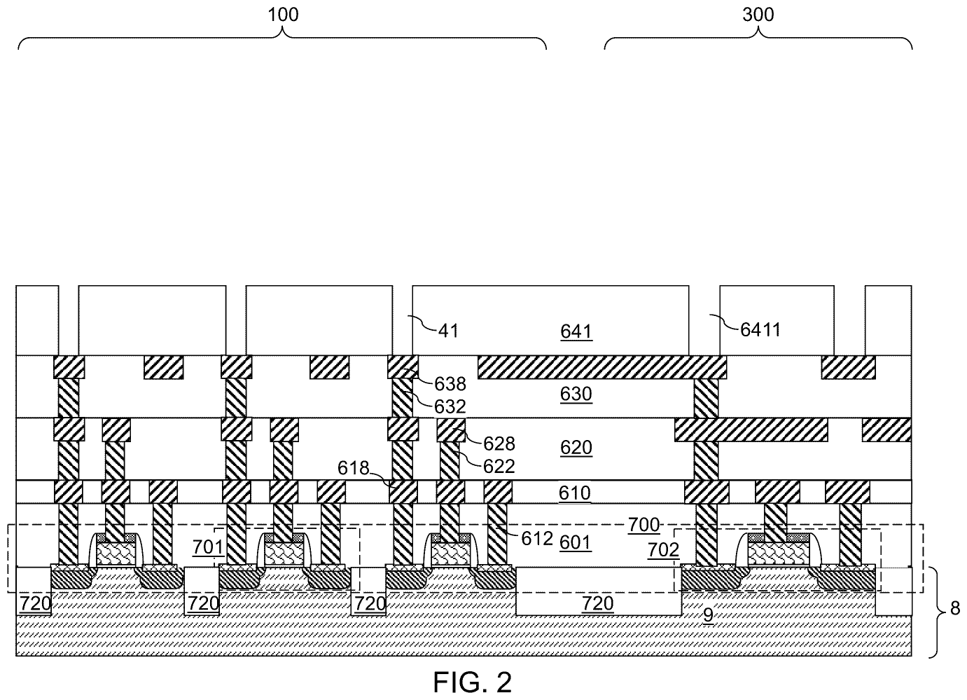

Referring to FIG. 2, via cavities 41 may be formed through a dielectric material layer (such as the lower fourth interconnect-level dielectric material layer 641). Each via cavity 41 may be formed over a respective one of the underlying metal interconnect structures (such as a subset of the third metal line structures 638) so that top surface segments of the underlying metal interconnect structures are physically exposed. The dielectric material layer, through which the via cavities 41 are formed, comprises a heat-resistant dielectric material such as undoped silicate glass or a doped silicate glass. The thickness of the dielectric material layer may be in a range from 200 nm to 1,000 nm, although lesser or greater thicknesses may also be used. The lateral dimension (such as the diameter) of each via cavity 41 may be in a range from 30 nm to 300 nm, although lesser or greater lateral dimensions may also be used. Peripheral via cavities 6411 may be formed through the dielectric material layer in the peripheral region 300.

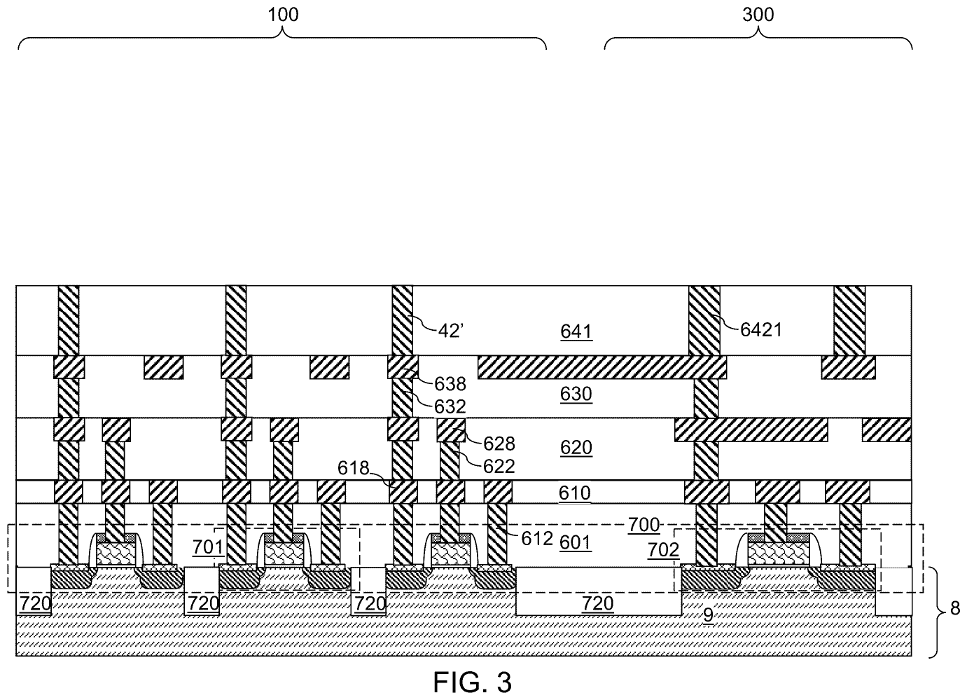

Referring to FIG. 3, a metallic fill material having a high electrical conductivity, such as copper or tungsten, may be deposited in the via cavities 41 and the peripheral via cavities 6411. A metallic liner material, such as a conductive metallic nitride material, may be optionally deposited as a thin liner prior to deposition of the metallic fill material. Excess portions of the metallic fill material may be removed from above the horizontal plane including the top surface of the dielectric material layer (such as the lower fourth interconnect-level dielectric material layer 641) by performing a planarization process, which may comprise a recess etch process and/or a chemical mechanical polishing process. Each remaining portion of the optional metallic liner material and the metallic fill material that fills a respective via cavity 41 constitutes an in-process bottom electrode 42′, which is subsequently modified to become a bottom electrode of a respective phase change memory cell. As used herein, an “in-process” element refers to an element that is subsequently modified structurally or compositionally. Each remaining portion of the optional metallic liner material and the metallic fill material that fills a peripheral via cavity 6411 constitutes a lower peripheral via structure 6421.

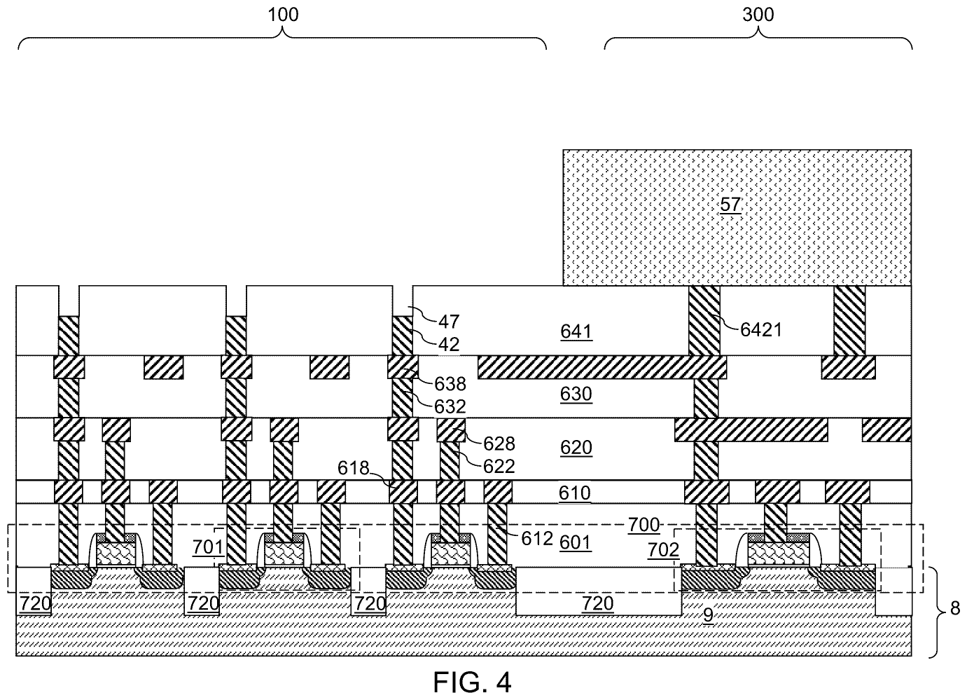

Referring to FIG. 4, a masking layer 57, such as a patterned photoresist layer, may be formed over the dielectric material layer (such as the lower fourth interconnect-level dielectric material layer 641) to cover the peripheral region 300 without covering the memory array region 100. A recess etch process may be performed to vertically recess the in-process bottom electrodes 42′ selectively to the material of the dielectric material layer, i.e., without removing the material of the dielectric material layer. The recess etch process may comprise a wet etch process or a reactive ion etch process. Upper portions of the in-process bottom electrodes 42′ may be removed by the recess etch process. Remaining portions of the in-process bottom electrodes 42′ constitute bottom electrodes 42 for the phase change memory cells to be subsequently formed. Heater cavities 47 may be formed in the volumes from which the upper portions of the in-process bottom electrodes 42′ may be removed. The height of the bottom electrodes 42 may be in a range from 100 nm to 800 nm, such as from 200 nm to 400 nm, although lesser or greater heights may also be used. The depth of the heater cavities 47 may be in a range from 100 nm to 800 nm, such as from 200 nm to 400 nm, although lesser or greater depths may also be used.

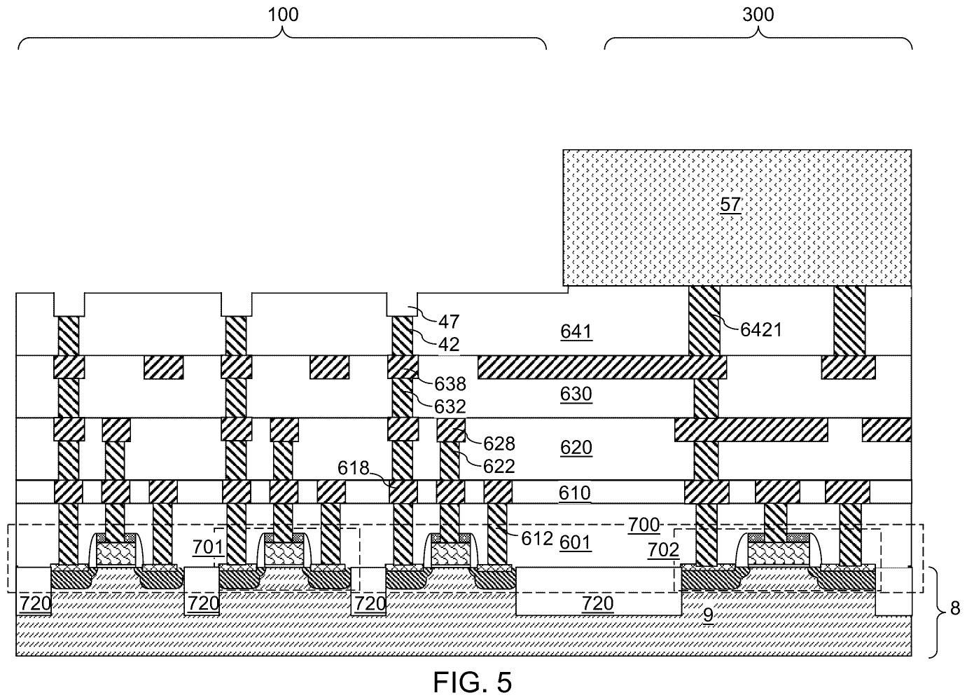

Referring to FIG. 5, an isotropic recess etch process may be performed to isotropically recess physically exposed surfaces of the dielectric material layer, which include sidewall surfaces of the heater cavities 47 and a planar top surface of the dielectric material layer. For example, in embodiments in which the dielectric material layer (such as the lower fourth interconnect-level dielectric material layer 641) comprises a silicate glass, the isotropic recess etch process may comprise a wet etch process using dilute hydrofluoric acid. The duration of the isotropic recess etch process may be selected such that the recess distance for the material of the dielectric material layer is in a range from 1 nm to 100 nm, such as from 5 nm to 50 nm, although lesser or greater recess distances may also be used. In this embodiment, the top surface of the dielectric material layer may have a step between the memory array region 100 and the peripheral region 300. In embodiments in which the isotropic recess etch process is performed, the heater cavities 47 may be laterally expanded. Generally, a metallic material to be subsequently deposited in the heater cavities 47 has a higher electrical resistivity than the metallic fill material of the bottom electrodes 42. The lateral expansion of heater cavities 47 may be advantageously used to optimize the electrical resistance of heater elements to be subsequently formed in the heater cavities 47. The masking layer 57 may be subsequently removed, for example, by ashing.

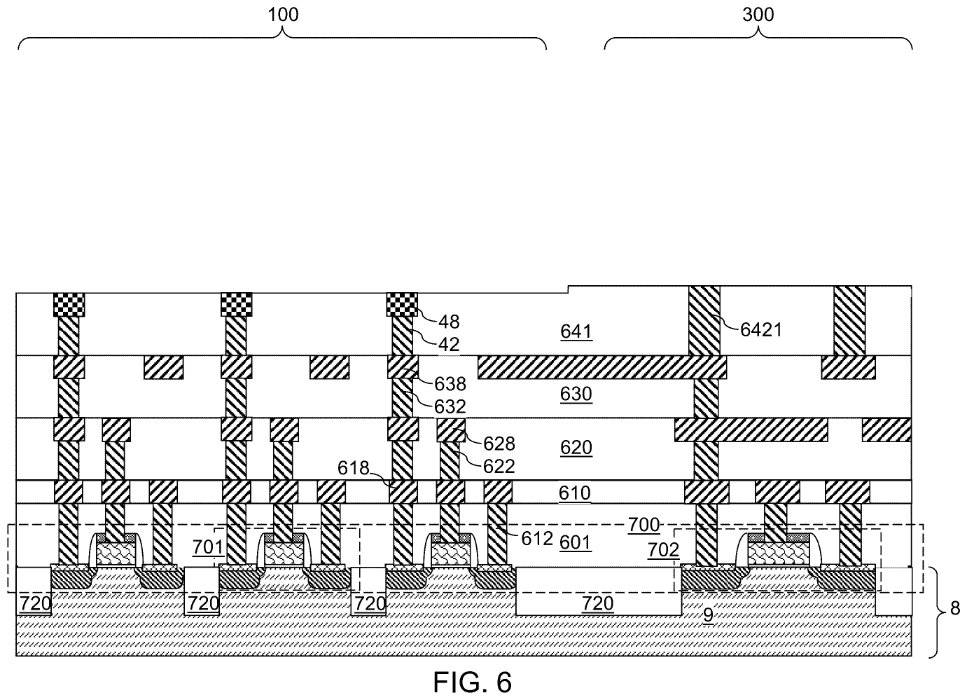

Referring to FIG. 6, a metallic heater material having higher electrical conductivity than the metallic fill material of the bottom electrodes 42 may be deposited in the heater cavities 47. The metallic heater material may comprise, and/or may consist essentially of, at least one metallic nitride material such as TiN, TaN, WN, and/or MoN. The metallic heater material may be deposited by chemical vapor deposition or physical vapor deposition. In one embodiment, the metallic heater material may comprise a stoichiometric or near-stoichiometric metallic nitride material, such as stoichiometric or near-stoichiometric TiN, TaN, WN, and/or MoN. If the heater cavities 47 have an aspect ratio (i.e., a height-to-width ratio) greater than 1, a conformal deposition process such as a chemical vapor deposition process may be used to deposit the metallic heater material.

A planarization process may be performed to remove portions of the metallic heater material that is deposited over the top surface of the dielectric material layer (such as the lower fourth interconnect-level dielectric material layer 641) that embeds the bottom electrodes 42. The planarization process may comprise a selective recess etch process that etches the metallic heater material selectively to the dielectric material of the dielectric material layer. Each remaining portion of the metallic heater material that fills a respective one of the heater cavities 47 constitutes a heater element 48. In one embodiment, top surface of the heater elements 48 may be coplanar with, or substantially coplanar with, the portion of the top surface of the dielectric material layer (such as the lower fourth interconnect-level dielectric material layer 641) located in the memory array region 100.

For each phase change memory cell to be subsequently formed, a bottom electrode 42 and a heater element 48 may be formed within a dielectric material layer (such as the lower fourth interconnect-level dielectric material layer 641). The heater element 48 is electrically connected to an electrical node (i.e., the output node) of a respective one of the programming transistors 701. In one embodiment, a two-dimensional array of stacks of a bottom electrode 42 and a heater element 48 may be formed in the memory array region 100.

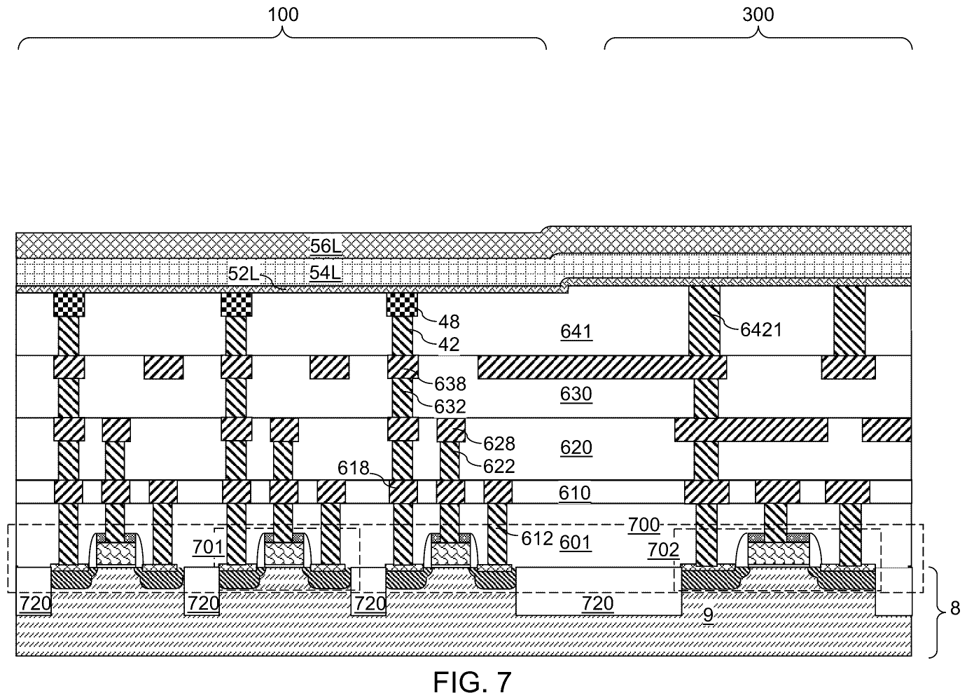

Referring to FIG. 7, a continuous layer stack (52L, 54L, 56L) including a bottom liner layer 52L, a phase change material layer 54L comprising a phase change material, and a top electrode material layer 56L may be sequentially deposited over the top surface of the dielectric material layer (such as the lower fourth interconnect-level dielectric material layer 641) that embeds the bottom electrodes 42 and the heater elements 48.

The bottom liner layer 52L comprises a first metallic nitride material, which may be a stoichiometric or near-stoichiometric metallic nitride material. For example, the bottom liner layer 52L may comprise TaN, TiN, WN, and/or MoN. In one embodiment, the electrical conductivity of the metallic material of the bottom liner layer 52L may be in a range from 1.0×10³ S/cm to 1.0×10⁵ S/cm. The thickness of the bottom liner layer 52L is selected such that patterned portions of the bottom liner layer 52L may provide electrical resistance during operation of phase memory cells to be subsequently formed. For example, the thickness of the bottom liner layer 52L may be in a range from 1 nm to 20 nm, such as from 2 nm to 4 nm, although lesser or greater thicknesses may also be used. The bottom liner layer 52L may be deposited by chemical vapor deposition or physical vapor deposition.

The phase change material layer 54L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge2Sb2Te5 or GeSb2Te4, germanium antimony compounds, indium germanium telluride compounds, aluminum selenium telluride compounds, indium selenium telluride compounds, and aluminum indium selenium telluride compounds. In one embodiment, the phase change material of the phase change material layer 54L may comprise a doped GST compound such as N-doped GST, Si-doped GST, C-doped GST, Ge-doped GST, Ru-doped GST, or Al-doped GST, or a doped GeTe compound such as N-doped GeTe, Si-doped GeTe, C-doped GeTe, or Ge-doped GeTe. The phase change material layer 54L may be deposited by physical vapor deposition. The thickness of the phase change material layer 54L may be in a range from 30 nm to 200 nm, such as from 50 nm to 90 nm, although lesser and greater thicknesses may also be used. In one embodiment, the phase change material of the phase change material layer may be selected such that the electrical conductivity of the amorphous phase of the phase change material is in a range from 1.0×10⁻⁸ S/cm to 1.0×10⁻³ S/cm, while the electrical conductivity of the crystalline phase of the phase change material is in a range from 1.0×10⁻¹ S/cm to 1.0×10³ S/cm.

The top electrode material layer 56L comprises a metallic material such as W, Ta, Ti, Mo, WN, TiN, WN, or MoN. The top electrode material layer 56L may have a thickness in a range from 100 nm to 200 nm, although lesser or greater thicknesses may also be used. The top electrode material layer 56L may be deposited by chemical vapor deposition or physical vapor deposition.

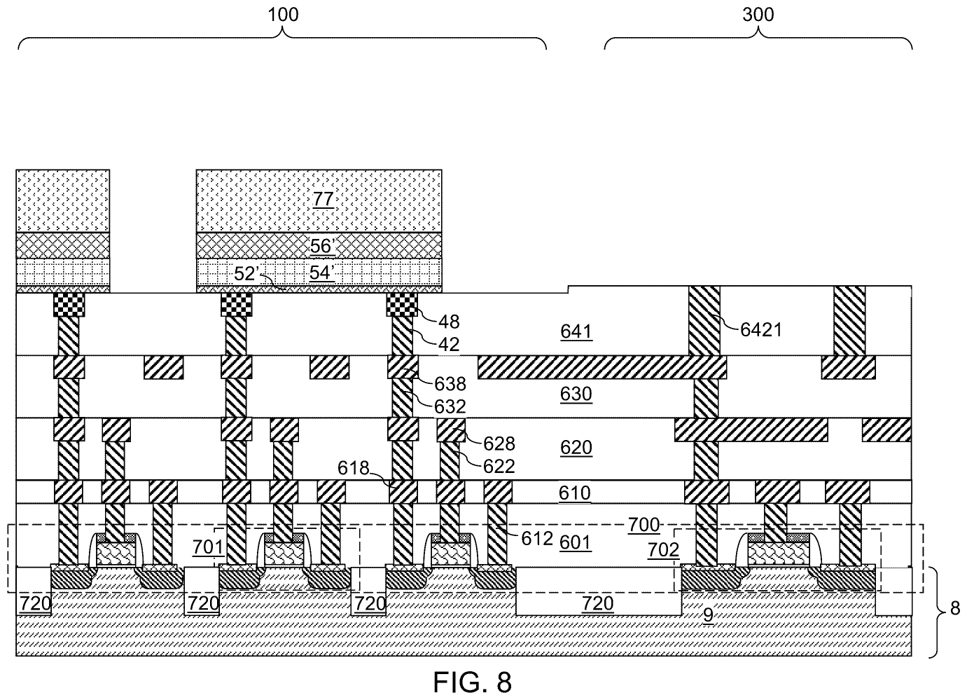

Referring to FIG. 8, a first patterning process may be performed to pattern the continuous layer stack (52L, 54L, 56L) into in-process layer stacks (52′, 54′, 56′). Specifically, a first patterned etch mask layer 77 may be formed over the continuous layer stack (52L, 54L, 56L). For example, the first patterned etch mask layer 77 may be formed by applying a photoresist layer over the continuous layer stack (52L, 54L, 56L), and lithographically patterning the photoresist layer into an array of discrete patterned photoresist material portions. In one embodiment, the first patterned etch mask layer 77 may comprise a two-dimensional array, such as a two-dimensional rectangular periodic array, of patterned photoresist material portions that is located in the memory array region 100. In one embodiment, each patterned photoresist material portion may have a rectangular horizontal cross-sectional shape. In one embodiment, the lateral dimensions of each patterned photoresist material portion may be selected to enable patterning of at least two phase change memory cells in subsequent processing steps. Alternatively, the lateral dimensions of each patterned photoresist material portion may be selected to enable patterning of a single phase change memory cell in subsequent processing steps.

A first anisotropic etch process may be performed to etch portions of the continuous layer stack (52L, 54L, 56L) that are not masked by the first patterned etch mask layer 77. The first anisotropic etch process has an etch chemistry that etches the materials of the continuous layer stack (52L, 54L, 56L) selectively to the material of the dielectric material layer (such as the lower fourth interconnect-level dielectric material layer 641) that embeds the heater elements 48. The continuous layer stack (52L, 54L, 56L) is patterned into in-process layer stacks (52′, 54′, 56′) each including an in-process bottom liner 52′, an in-process phase change material portion 54′, and an in-process top electrode 56′. As used herein, an “in-process” element refers to an element that is structurally and/or compositionally modified in a subsequent processing step. Each in-process bottom liner 52′ is a patterned portion of the bottom liner layer 52L. Each in-process phase change material portion 54′ is a patterned portion of the phase change material layer 54L. Each in-process top electrode 56′ is a patterned portion of the top electrode material layer 56L. For each in-process layer stack (52′, 54′, 56′), the sidewalls of the in-process bottom liner 52′ may be vertically coincident with the sidewalls of the in-process phase change material portion 54′, and may be vertically coincident with the sidewalls of the in-process top electrode 56′. As used herein, a first surface is “vertically coincident” with a second surface in which the second surface overlies or underlies the first surface and in which the first surface and the second surface are located within a same vertical plane, which may be planar or curved in a horizontal cross-sectional view. The first patterned etch mask layer 77 may be subsequently removed, for example, by ashing.

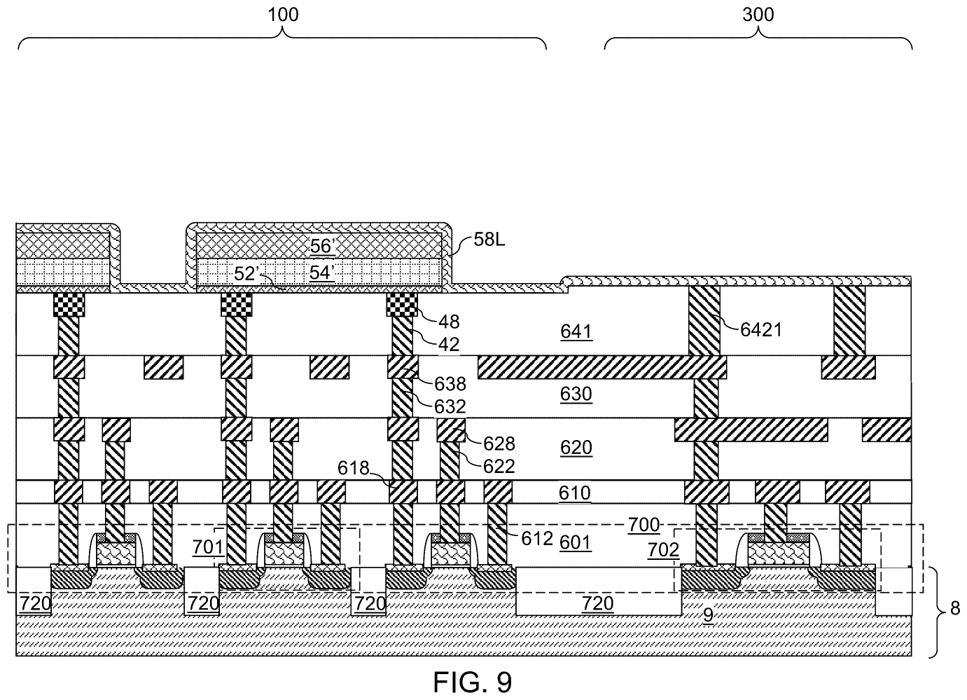

Referring to FIG. 9 and according to an aspect of the present disclosure, a sidewall liner layer 58L may be deposited on the physically exposed surfaces of the in-process layer stacks (52′, 54′, 56′) and on the physically exposed top surface of the dielectric material layer (such as the lower fourth interconnect-level dielectric material layer 641) that embeds the bottom electrodes 42 and the heater elements 48. In one embodiment, the sidewall liner layer 58L may comprise a metallic nitride material layer that is deposited by a conformal deposition process such as a chemical vapor deposition process. In one embodiment, the sidewall liner layer 58L may comprise a second metallic nitride material, which may comprise, and/or may consist essentially of, TiN, TaN, WN, and/or MoN. The thickness of the sidewall liner layer 58L may be in a range from 1 nm to 20 nm, such as from 2 nm to 4 nm, although lesser or greater thicknesses may also be used.

According to an aspect of the present disclosure, the electrical conductivity of the second metallic nitride material may be reduced by incorporating carbon atoms or nitrogen atoms into the metallic nitride material layer by in-situ doping or ex-situ doping of carbon atoms or nitrogen atoms, i.e., incorporation of the carbon atoms or the nitrogen atoms during deposition of the sidewall liner layer 58L or after deposition of the sidewall liner layer 58L. For example, the carbon atoms or the nitrogen atoms may be provided by a reactive carbon-containing gas (such as acetylene or ethylene) or a reactive nitrogen-containing gas (such as ammonia) during a chemical vapor deposition that deposits the sidewall liner layer 58L. Alternatively, the sidewall liner layer 58L may be exposed to an ambient containing reactive carbon-containing species or reactive nitrogen-containing species at an elevated temperature after the deposition process that deposits the sidewall liner layer 58L. Yet alternatively, an ion implantation process or a plasma doping process may be performed after the deposition process that deposits the sidewall liner layer 58L.

The carbon atoms or the nitrogen atoms are incorporated into the second metallic nitride material of the sidewall liner layer 58L at an atomic concentration such that the electrical conductivity of the doped metallic nitride material of the sidewall liner layer 58L after incorporation of the carbon atoms or the nitrogen atoms is less than ⅓ of the electrical conductivity of the second metallic nitride material prior to the incorporation of the carbon atoms or the nitrogen atoms. In an illustrative example, the electrical conductivity of the sidewall liner layer 58L after incorporation of the carbon atoms or the nitrogen atoms may be in a range from 1.0×10¹ S/cm to 1.0×10⁵ S/cm.

Generally, the ratio of the metal atoms to nitrogen atoms in a stoichiometric metallic compound MN, in which M is Ta, Ti, Mo, or W, is 1:1. In embodiments in which nitrogen doping is used, upon doping of a stoichiometric metallic compound with nitrogen atoms to form the sidewall liner layer 58L of the present disclosure, the ratio of the metal atoms to nitrogen atoms in the sidewall liner layer 58L may be in a range from 1:1.02 to 1:1.05. In embodiments in which carbon doping is used, upon doping of a stoichiometric metallic compound with carbon atoms to form the sidewall liner layer 58L of the present disclosure, the ratio of the metal atoms to nitrogen atoms to carbon atoms in the sidewall liner layer 58L may be in a range from 1:1:0.02 to 1:1:0.05. Generally, the atomic concentration of the extra nitrogen atoms in a nitrogen-doped metallic nitride material may be in a range from 0.02 times the atomic concentration of the metal atoms to 0.05 times the atomic concentration of the metal atoms. Likewise, the atomic concentration of the carbon atoms in a carbon-doped metallic nitride material may be in a range from 0.02 times the atomic concentration of the metal atoms to 0.05 times the atomic concentration of the metal atoms.

In one embodiment, the second metallic nitride material of the sidewall liner layer 58L after the doping process may have an electrical conductivity that is less than ⅓, and preferably less than 1/10, of an electrical conductivity of the first metallic nitride material of the in-process bottom liners 52′. In other words, the in-process bottom liners 52′ comprise a material having an electrical conductivity that is at least 3 times, and preferably at least 10 times, the electrical conductivity of the sidewall liner material of the sidewall liner layer 58L.

Generally, the first metallic nitride material of the bottom liner layer 52L (and of the in-process bottom liners 52′) and the second metallic nitride material (which is a doped metallic nitride material) of the sidewall liner layer 58L are selected such that the resistance of a bottom liner to be patterned from an in-process bottom liner 52′ and the resistance of a sidewall liner to be patterned from the sidewall liner layer 58L dominate the resistance of states of phase memory material cells having high resistance values, which include the high resistance state and intermediate resistance states having relatively high resistance values. In this embodiment, the resistance of the amorphous volume of a phase change material portion does not determine the resistance of high resistance states of a phase change memory cell. Thus, the phase change memory cell may operate without being affected by any resistance drift of a phase change material.

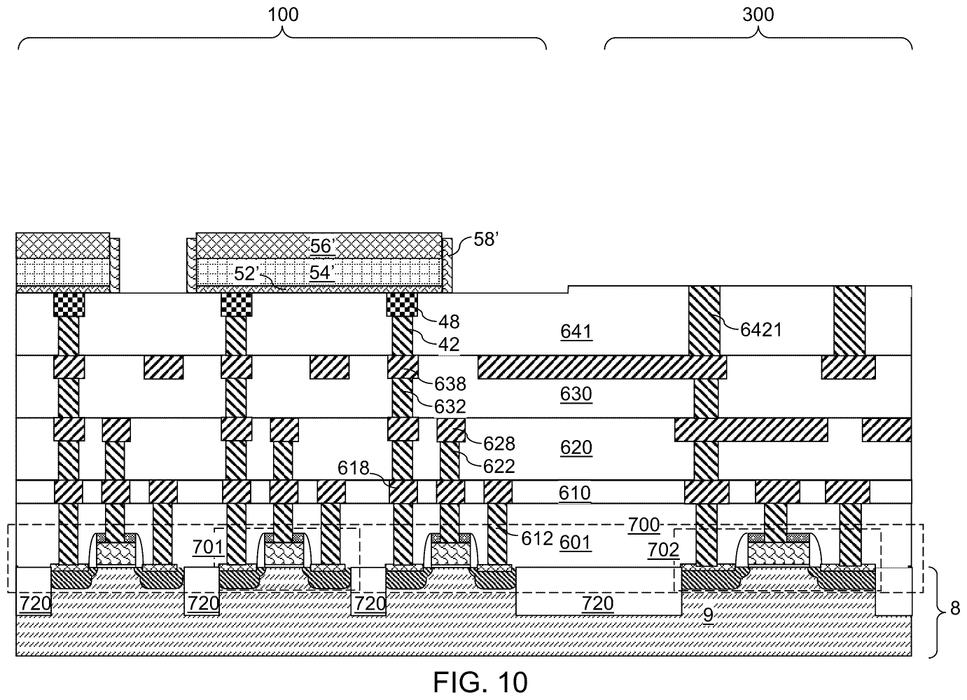

Referring to FIG. 10, an anisotropic etch process may be performed to remove horizontally-extending portions of the sidewall liner layer 58L. The anisotropic etch process may be selective to the material of the dielectric material layer (such as the lower fourth interconnect-level dielectric material layer 641) having formed therein the heater elements 48. Each remaining vertically-extending portion of the sidewall liner layer 58L constitutes an in-process sidewall liner 58′ that laterally surrounds a respective in-process layer stack (52′, 54′, 56′). Each in-process sidewall liner 58′ contacts each sidewall of the in-process bottom liner 52′, the in-process phase change material portion 54′, and the in-process top electrode 56′ of a respective in-process layer stack (52′, 54′, 56′). In one embodiment, an upper surface segment of each sidewall of the in-process top-electrodes 56′ may be physically exposed. Generally, an in-process sidewall liner 58′ may be formed around each in-process layer stack (52′, 54′, 56′) by conformally depositing and anisotropically etching a layer of the sidewall liner material.

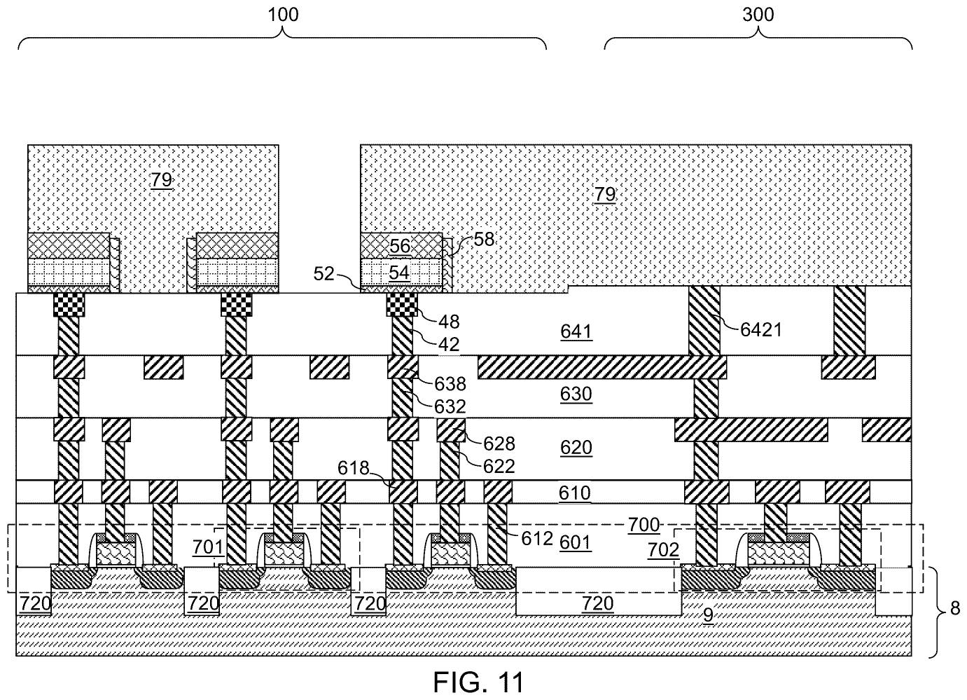

Referring to FIG. 11, a second patterning process may be performed to pattern the in-process layer stacks (52′, 54′, 56′) and the in-process sidewall liners 58′. A second patterned etch mask layer 79 may be formed over the in-process layer stacks (52′, 54′, 56′) and the in-process sidewall liners 58′ in a manner that covers first areas of the in-process layer stacks (52′, 54′, 56′) and the in-process sidewall liners 58′ without covering second areas of the in-process layer stacks (52′, 54′, 56′) and the in-process sidewall liners 58′. For example, a photoresist layer (not shown) may be applied over the in-process layer stacks (52′, 54′, 56′) and the in-process sidewall liners 58′, and may be lithographically patterned into a two-dimensional array, such as a rectangular array, of patterned photoresist material portions. In one embodiment, the second patterned etch mask layer 79 may cover at least two discrete areas of each in-process layer stack (52′, 54′, 56′) that are not interconnected, i.e., that are separated by a gap that is not covered by the second patterned etch mask layer 79.

A second anisotropic etch process may be performed to etch unmasked portions of the in-process layer stacks (52′, 54′, 56′) and the in-process sidewall liners 58′, i.e., to etch the portions of the in-process layer stacks (52′, 54′, 56′) and the in-process sidewall liners 58′ that are not masked by the second patterned etch mask layer 79. The second anisotropic etch process has an etch chemistry that etches the materials of the in-process layer stacks (52′, 54′, 56′) and the in-process sidewall liners 58′ selectively to the material of the dielectric material layer (such as the lower fourth interconnect-level dielectric material layer 641) embedding the heater elements 48.

In one embodiment, the second patterning process may pattern each contiguous combination of an in-process layer stacks (52′, 54′, 56′) and an in-process sidewall liners 58′ into multiple discrete material portions that are not adjoined to one another. In one embodiment, each patterned portion of an in-process layer stack (52′, 54′, 56′) comprises a respective layer stack including a bottom liner 52, a phase change material portion 54, and a top electrode 56. Each patterned portion of an in-process sidewall liner 58′ constitutes a sidewall liner 58 according to an embodiment of the present disclosure. An in-process layer stacks (52′, 54′, 56′) may be patterned into a plurality of layer stacks (52, 54, 56). An in-process sidewall liner 58′ may be patterned into a plurality of sidewall liners 58. For each layer stack (52, 54, 56), the lateral distance between a sidewall of the layer stack (52, 54, 56) and a proximal sidewall of an underlying heater element 48 may be in a range from 30 nm to 200 nm, such as from 50 nm to 150 nm, although lesser or greater lateral distances may also be employed.

Generally, at least one sidewall liner 58 may be formed on a sidewall of each layer stack (52, 54, 56), which is a patterned portion of the continuous layer stack (52L, 54L, 56L), by depositing and patterning a sidewall liner material. The sidewall liner material of the at least one sidewall liner 58 comprises a material having an electrical conductivity that is higher than an electrical conductivity of an amorphous phase of the phase change material. The sidewall liner material may comprise a metallic nitride material formed by incorporating carbon atoms or nitrogen atoms therein such that the metallic nitride material has a lower electrical conductivity than a stoichiometric metallic nitride material. Thus, in embodiments in which an amorphous phase portion of a phase change material and a sidewall liner 58 provide two parallel electrically conductive paths, the sidewall liner 58 provides a lower resistance path, and predominantly determines the total resistance of the two parallel electrically conductive paths during operation of the phase change memory cell of the present disclosure. This aspect is particularly useful for operation of the phase change memory cell for computation-in-memory (CIM) applications because the resistance drift effect of the phase change material is suppressed during operation of the phase change memory cell.

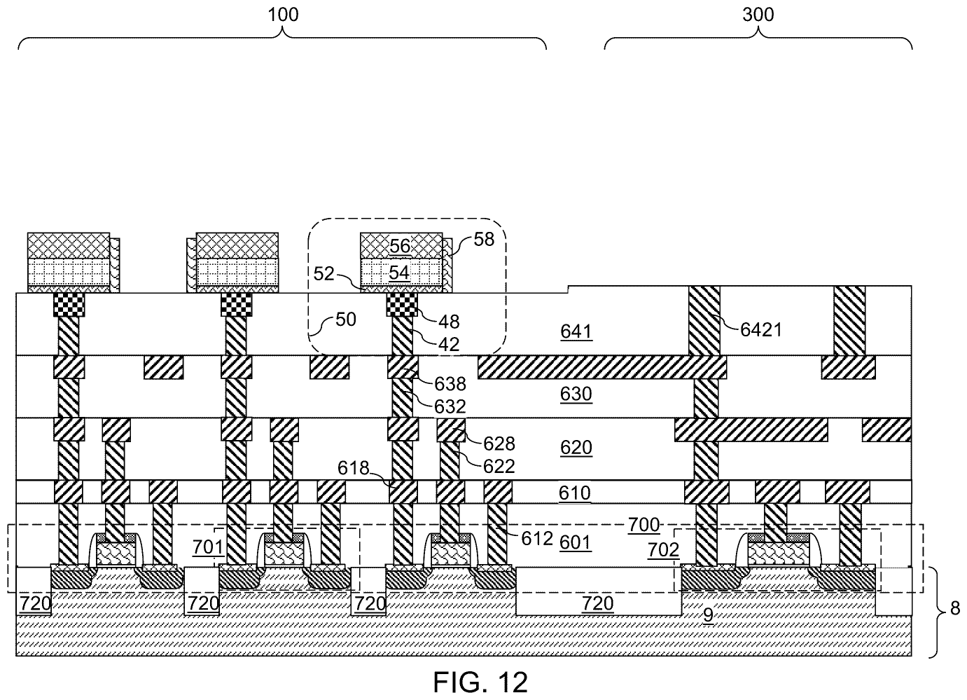

Referring to FIG. 12, the second patterned etch mask layer 79 may be removed, for example, by ashing. Each contiguous combination of a bottom electrode 42, a heater element 48, a bottom liner 52, a phase change material portion 54, a top electrode 56, and at least one sidewall liner 58 constitutes a phase change memory cell 50. A two-dimensional array of phase change memory cells 50 may be provided.

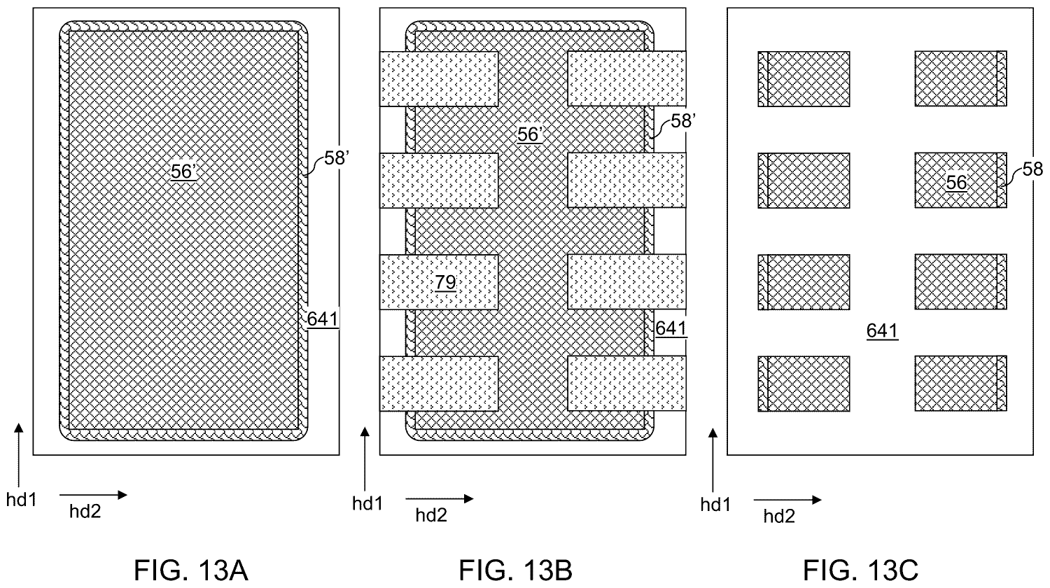

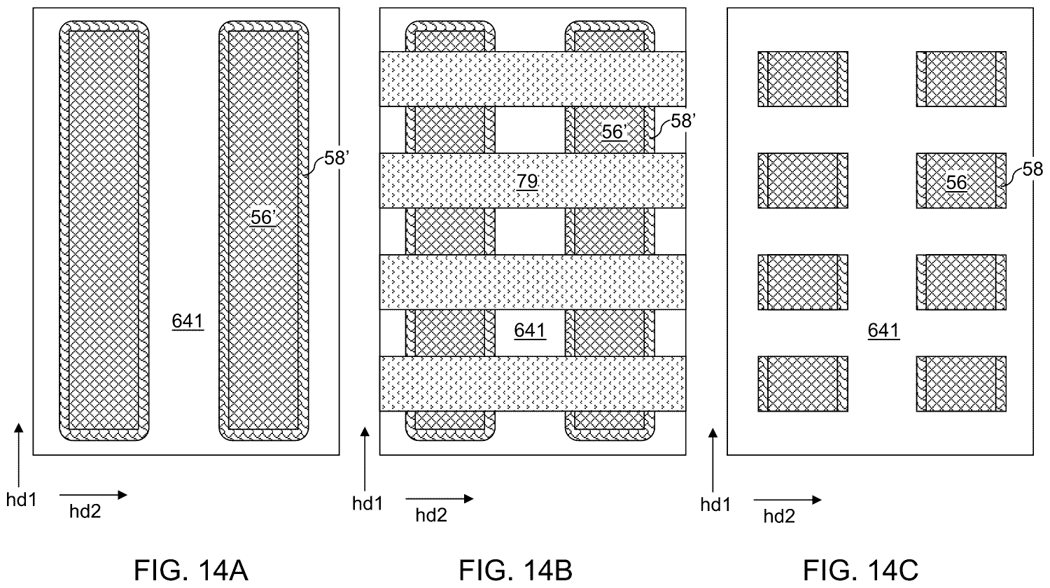

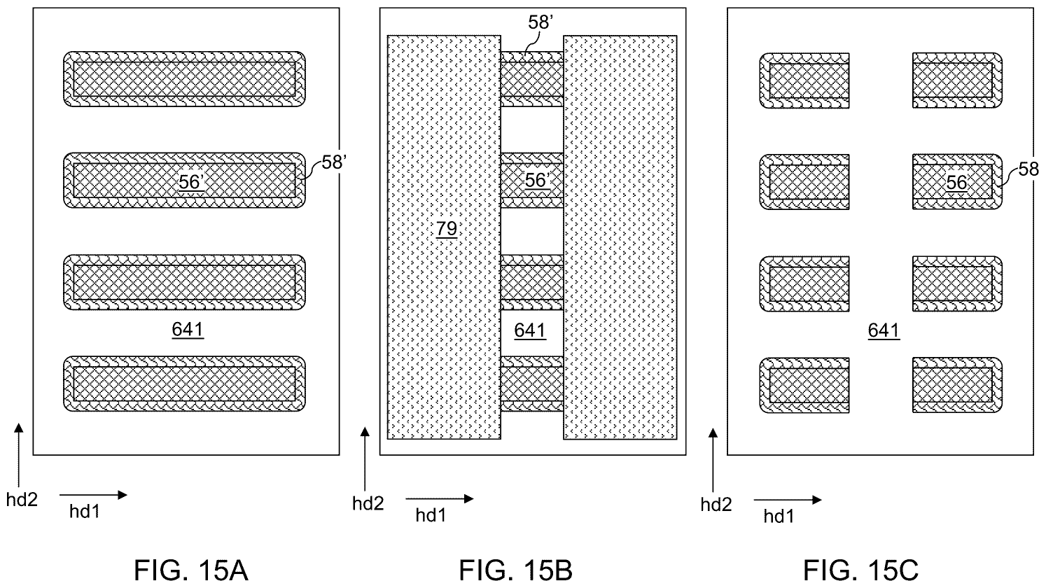

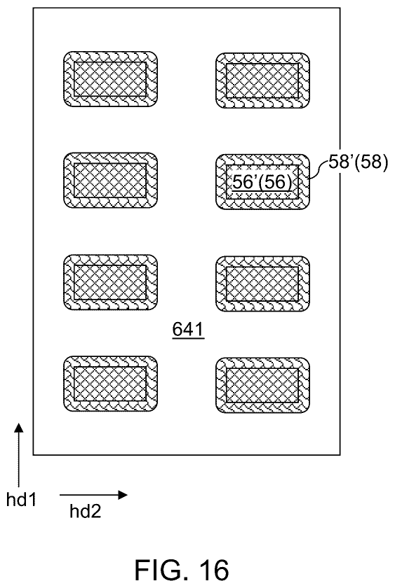

Generally, the first patterning process described with reference to FIG. 8 and the second patterning process described with reference to FIG. 11 may use various combinations of patterns to provide an array of phase change memory cells 50 having different configurations. FIGS. 13A-13C illustrate sequential top-down views of a region of a first configuration of the embodiment structure during the processing steps of FIGS. 10-12. FIGS. 14A-14C illustrate sequential top-down views of a region of a second configuration of the embodiment structure during the processing steps of FIGS. 10-12. FIGS. 15A-15C illustrate sequential top-down views of a region of a third configuration of the embodiment structure during the processing steps of FIGS. 10-12. FIG. 16 illustrates a top-down view of a region of a fourth configuration of the embodiment structure after the processing steps of FIG. 10. The various configurations illustrated in FIGS. 13A-16 are mere illustrations that describe specific configurations, and do not limit the scope of the present disclosure.

Referring to FIG. 13A, a region of a first configuration of the embodiment structure including an in-process layer stack (52′, 54′, 56′) and an in-process sidewall liner 58′ is illustrated at a processing step of FIG. 10. The in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 13B, the region of the first configuration of the embodiment structure is illustrated after formation of the second patterned etch mask layer 79 and prior to performing the second anisotropic etch process. The second patterned etch mask layer 79 may comprise a two-dimensional array, such as a 2×N array, of patterned discrete etch mask material portions (such as patterned photoresist material portions) that cover 2N segments of the first sidewalls of the in-process layer stack (52′, 54′, 56′). In the illustrated example, the integer N is 4. Generally, the integer N may be any positive integer. As discussed above, the in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 13C, the second anisotropic etch process may be performed as described with reference to FIG. 11. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the first configuration illustrated in FIG. 13C, the at least one row of patterned portions may comprise two rows of patterned portions of the in-process layer stack (52′, 54′, 56′), i.e., two rows of layer stacks (52, 54, 56) that constitute a 2×N array of layer stacks (52, 54, 56). Generally, a P×Q array of in-process layer stacks (52′, 54′, 56′) may be used, and a 2P×QN array of phase change memory cells 50 may be formed by using the first configuration illustrated in FIGS. 13A-13C.

Generally speaking, the at least one sidewall liner 58 may be formed on each layer stack (52, 54, 56) within each phase change memory cell 50. In the first configuration, the at least one sidewall liner 58 within each phase change memory cell 50 may consist of a single sidewall liner 58 that is formed directly on a sidewall of the layer stack (52, 54, 56) of the phase change memory cell 50, which is a patterned portion of the continuous layer stack (52L, 54L, 56L).

Referring to FIG. 14A, a region of a second configuration of the embodiment structure including two in-process layer stacks (52′, 54′, 56′) and two in-process sidewall liners 58′ is illustrated at a processing step of FIG. 10. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 14B, the region of the second configuration of the embodiment structure is illustrated after formation of the second patterned etch mask layer 79 and prior to performing the second anisotropic etch process. The second patterned etch mask layer 79 may comprise a 1×N array of patterned discrete etch mask material portions (such as patterned photoresist material portions) that cover 2N segments of the first sidewalls of each in-process layer stack (52′, 54′, 56′). Each patterned discrete etch mask material portion may comprise a photoresist material strip that laterally extends along the second horizontal direction hd2 and having a uniform width along the first horizontal direction hd1. In the illustrated example, the integer N is 4. Generally, the integer N may be any positive integer. As discussed above, each in-process layer stack (52′, 54′, 56′) comprises first sidewalls that laterally extend along the first horizontal direction hd1 and second sidewalls that laterally extend along the second horizontal direction hd2. The masking material portions of the second patterned etch mask layer 79 laterally extend along the second horizontal direction hd2, and may be laterally spaced apart from one another along the first horizontal direction hd1.

Referring to FIG. 14C, the second anisotropic etch process may be performed as described with reference to FIG. 11. The second anisotropic etch process removes unmasked portions of the in-process layer stack (52′, 54′, 56′) that are not covered by the second patterned etch mask layer 79. Each patterned portion of the in-process layer stack (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the second configuration illustrated in FIG. 14C, the at least one row of patterned portions may comprise a row of patterned portions of the in-process layer stack (52′, 54′, 56′), i.e., a row of layer stacks (52, 54, 56) that constitutes a 1×N array of layer stacks (52, 54, 56). Generally, a P×Q array of in-process layer stacks (52′, 54′, 56′) may be used, and a P×QN array of phase change memory cells 50 may be formed by using the second configuration illustrated in FIGS. 14A-14C.

Generally speaking, the at least one sidewall liner 58 may be formed on each layer stack (52, 54, 56) within each phase change memory cell 50. In the second configuration, the at least one sidewall liner 58 within each phase change memory cell 50 may comprise two sidewall liners 58 that are formed directly on a pair of sidewalls of the layer stack (52, 54, 56) of the phase change memory cell 50, which is a patterned portion of the continuous layer stack (52L, 54L, 56L). The pair of sidewalls may be parallel to each other, and the two sidewall liners 58 are laterally spaced apart from each other along a horizontal direction such as the second horizontal direction hd2.

Referring to FIG. 15A, a region of a third configuration of the embodiment structure including in-process layer stacks (52′, 54′, 56′) and in-process sidewall liners 58′ is illustrated at a processing step of FIG. 10. Each in-process layer stack (52′, 54′, 56′) may comprise first sidewalls that are parallel to a first horizontal direction hd1 and second sidewalls that are parallel to a second horizontal direction hd2. The second horizontal direction hd2 may be perpendicular to the first horizontal direction hd1.

Referring to FIG. 15B, the region of the third configuration of the embodiment structure is illustrated after formation of the second patterned etch mask layer 79 and prior to performing the second anisotropic etch process. The second patterned etch mask layer 79 may comprise a pair of patterned discrete etch mask material portions (such as patterned photoresist material portions) that cover all second sidewalls of the in-process layer stacks (52′, 54′, 56′) and segments of each first sidewall that are adjoined to a respective second sidewall of the in-process layer stacks (52′, 54′, 56′). Each first sidewall of the in-process layer stacks (52′, 54′, 56′) comprises a central segment that is not covered by the second patterned etch mask layer 79. As discussed above, each in-process layer stack (52′, 54′, 56′) comprises first sidewalls that laterally extend along the first horizontal direction hd1 and second sidewalls that laterally extend along the second horizontal direction hd2. The two masking material portions of the second patterned etch mask layer 79 laterally extend along the second horizontal direction hd2, and may be laterally spaced apart from one another along the first horizontal direction hd1 so that central segments of each first sidewall of the in-process layer stacks (52′, 54′, 56′) are not covered by the second patterned etch mask layer 79.

Referring to FIG. 15C, the second anisotropic etch process may be performed as described with reference to FIG. 11. The second anisotropic etch process removes unmasked portions of the in-process layer stacks (52′, 54′, 56′) that are not covered by the second patterned etch mask layer 79. Each patterned portion of the in-process layer stacks (52′, 54′, 56′) comprises a layer stack (52, 54, 56) including a respective bottom liner 52, a respective phase change material portion 54, and a respective top electrode 56. Generally, the multiple patterned portions of each in-process layer stack (52′, 54′, 56′) may comprise at least one row of patterned portions arranged along the first horizontal direction hd1. In the third configuration illustrated in FIG. 15C, the at least one row of patterned portions may comprise a row including two patterned portions of the in-process layer stack (52′, 54′, 56′), i.e., a row of layer stacks (52, 54, 56) that constitutes a 1×2 array of layer stacks (52, 54, 56). Generally, a P×Q array of in-process layer stacks (52′, 54′, 56′) may be used, and a P×2Q array of phase change memory cells 50 may be formed by using the third configuration illustrated in FIGS. 15A-15C.

Generally speaking, the at least one sidewall liner 58 may be formed on each layer stack (52, 54, 56) within each phase change memory cell 50. In the third configuration, the at least one sidewall liner 58 within each phase change memory cell 50 may consist of a single sidewall liner 58 that is formed directly on three sidewalls of the layer stack (52, 54, 56) of the phase change memory cell 50, which is a patterned portion of the continuous layer stack (52L, 54L, 56L).

Referring to FIG. 16, a fourth configuration of the embodiment structure is illustrated after the processing steps of FIG. 10. In the fourth configuration, the masking pattern of the first patterned etch mask layer 77 used at the processing steps of FIG. 8 is modified such that the pattern of the first patterned etch mask layer 77 is the same as the target pattern for an array of layer stacks (52, 54, 56) for an array of phase change memory cells 50. In this embodiment, the first anisotropic etch process described with reference to FIG. 8 patterns the continuous layer stack (52L, 54L, 56L) directly into the array of layer stacks (52, 54, 56). Further, upon performing the processing steps described with reference to FIGS. 9 and 10, the sidewall liner layer 58L may be patterned directly into the sidewall liners 58. Therefore, the processing steps described with reference to FIGS. 11 and 12 may be omitted if the fourth configuration of the embodiment structure is used.

Generally speaking, the at least one sidewall liner 58 may be formed on each layer stack (52, 54, 56) within each phase change memory cell 50. In the fourth configuration, the at least one sidewall liner 58 within each phase change memory cell 50 may have an annular configuration. In other words, the at least one sidewall liner 58 within each phase change memory cell 50 may consist of a single sidewall liner 58 that is topologically homeomorphic to a torus, i.e., may be continuous deformed without formation of a new hole and without elimination of any pre-existing hole into a torus. The single sidewall liner 58 may be formed directly on each sidewall of a respective layer stack (52, 54, 56), which is a patterned portion of the continuous layer stack (52L, 54L, 56L).

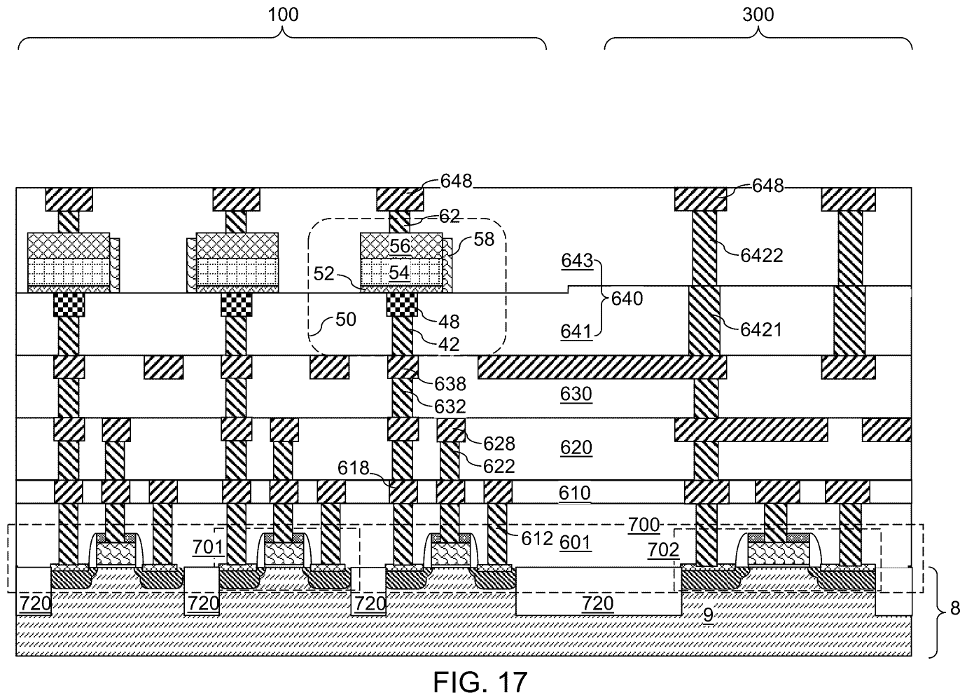

Referring to FIG. 17, an encapsulation dielectric layer 643 and additional metal interconnect structures (62, 6422, 648) may be formed over the phase change memory cells 50. The encapsulation dielectric layer 643 comprises at least one interlayer dielectric material such as silicon oxide, silicon nitride, and/or silicon carbide nitride. The additional metal interconnect structures (62, 6422, 648) may comprise top-contact via structures 62 contacting a top surface of a respective one of the top electrodes 56, upper peripheral via structures 6422 that are formed on lower peripheral via structures 6421, and fourth metal line structures 648 that are formed on the top-contact via structures 62 and the upper peripheral via structures 6422. Top surfaces of the fourth metal line structures 648 may be coplanar with the horizontal top surface of the encapsulation dielectric layer 643. The encapsulation dielectric layer 643 constitutes an upper fourth interconnect-level dielectric material layer. The combination of the lower fourth interconnect-level dielectric material layer 641 and the encapsulation dielectric layer 643 constitutes a fourth interconnect-level dielectric material layer 640. Additional dielectric material layers (not shown) and additional metal interconnect structures may be formed as needed to provide electrical connections between the top electrodes 56 of the phase change memory cells 50 and the various semiconductor devices 700 that underlie the dielectric material layers (601, 610, 620, 630, 640).

Generally, programming transistors 701 may be provided on a substrate 8. Metal interconnect structures (612, 618, 622, 628, 632, 638, 42, 6421) embedded within interconnect-level dielectric material layers (601, 610, 620, 630, 641) may be formed over the programming transistors 701. Bottom electrodes 42 and heater elements 48 may be formed within a dielectric material layer, such as a lower fourth interconnect-level dielectric material layer 641. Each heater element 48 is electrically connected to an electrical node, such as an output node, of a respective programming transistor 701. A continuous layer stack (52L, 54L, 56L) including a bottom liner layer 52L, a phase change material layer 54L comprising a phase change material, and a top electrode material layer 56L may be deposited and patterned to form layer stacks (52, 54, 56) of a bottom liner 52, a phase change material portion 54, and a top electrode 56. A sidewall liner layer 58L may be formed and patterned to form sidewall liners 58. At least one sidewall liner 58 may be formed on at least one sidewall of each layer stack (52, 54, 56).

Each sidewall liner 58 comprises a material having an electrical conductivity that is higher than an electrical conductivity of an amorphous phase of the phase change material of the phase change material portions 54. For each phase change memory cell 50, an encapsulation dielectric layer 643 may be deposited directly on at least one sidewall of the layer stack (52, 54, 56) (which is a patterned portion of the continuous layer stack (52L, 54L, 56L)) and directly on an outer sidewall of each of the at least one sidewall liner 58 and directly on a top surface of the layer stack (52, 54, 56). Thus, for each phase change memory cell 50, the encapsulation dielectric layer 643 is in contact with at least one sidewall of the layer stack, an outer sidewall of each of the at least one sidewall liner 58, and a top surface of the layer stack (52, 54, 56).

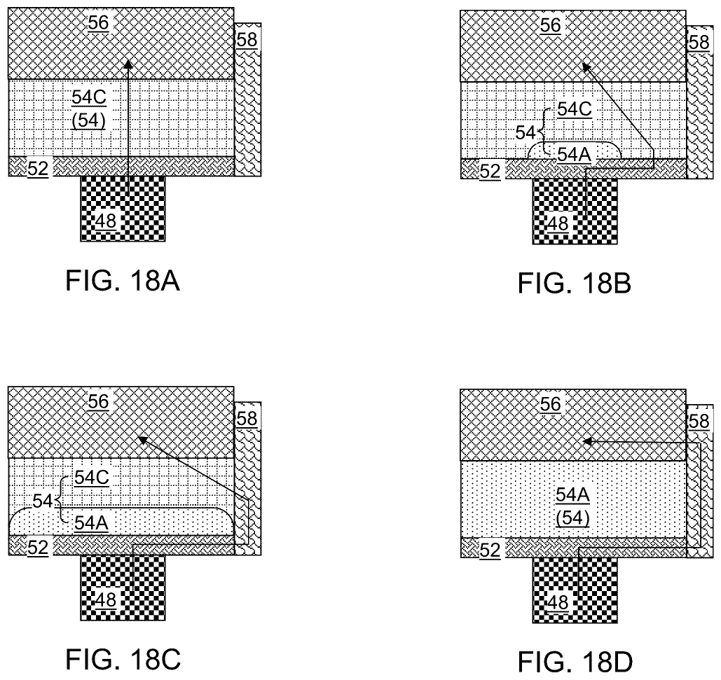

For each phase change memory cell 50 that is electrically connected to a programming transistor 701, the programming transistor 701 is configured to program the phase change memory cell 50 into at least three different resistive states by applying at least three different programming pulse patterns to the heater element 48. FIGS. 18A-18D are various configurations of a phase change material portion 54 in various programmed resistance states according to an embodiment of the present disclosure.

Referring to FIG. 18A, a phase change memory cell 50 in a low resistance state is illustrated. In this embodiment, at least 99% of the entire volume of the phase change material portion 54 is in a polycrystalline phase. In one embodiment, the entirety of the phase change material portion 54 may be a crystalline phase change material portion 54C including a polycrystalline phase change material. The electrical conductivity of the crystalline phase change material is higher than the electrical conductivity of the materials of the bottom liner 52 and the at least one sidewall liner 58. Thus, the primary electrically conductive path extends vertically between the heater element 48 and the top electrode 56.

Referring to FIG. 18B, a phase change memory cell 50 in a first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is not in direct contact with the at least one sidewall liner 58. The electrical conductivity of the amorphous phase change material is lower than the electrical conductivity of the materials of the bottom liner 52 and the at least one sidewall liner 58. Thus, the primary electrically conductive path extends laterally within the bottom liner 52 underneath the amorphous phase change material portion 54A and extends through the crystalline phase change material portion 54C between a peripheral portion of the bottom liner 52 and the top electrode 56 at an angle relative to the vertical direction.

Referring to FIG. 18C, a phase change memory cell 50 in a second intermediate state providing a higher resistance than the first intermediate state is illustrated. In this embodiment, the phase change material portion 54 comprises a first volume having the amorphous phase and a second volume having the crystalline phase. The first volume comprises an amorphous phase change material portion 54A, and the second volume comprises a crystalline phase change material portion 54C. The first volume is in direct contact with the at least one sidewall liner 58, and does not contact the top electrode 56. The electrical conductivity of the amorphous phase change material is lower than the electrical conductivity of the materials of the bottom liner 52 and the at least one sidewall liner 58. Thus, the primary electrically conductive path extends laterally within the bottom liner 52 underneath the amorphous phase change material portion 54A, extends vertically through a lower portion of each sidewall liner 58, and extends through the crystalline phase change material portion 54C between a middle portion of each sidewall liner 58 and the top electrode 56 at an angle relative to the vertical direction.

Referring to FIG. 18D, a phase change memory cell 50 in a high resistance state is illustrated. In this embodiment, at least 99% of an entire volume of the phase change material portion 54 is in an amorphous phase.

While four resistive states of a phase change memory cell 50 are illustrated in FIGS. 18A-18D, the pulse pattern of the programming pulse from the programming transistor 701 may be pre-programmed to be selected from a plurality of programming pulse patterns that is stored in a programming circuit for the phase change memory cells 50. The total number of pre-programmed pulse patterns may be in a range from 2 to 210, such as from 3 to 28, and/or from 4 to 26. The total number of resistive states that may be programmed in each phase change memory cell 50 may be the same as the total number of pre-programmed pulse patterns. In one embodiment, each programming transistor 701 may be configured to apply at least four different programming pulse patterns to a respective heater element 48. The programming pulses may have a respective duration and/or voltage ramp-down rate to enable a controlled rate of cooling of a molten region of a phase change material portion 54. The duration of the programming pulses may be in a range from 10 nanoseconds to 500 nanoseconds, the longer programming pulses generally corresponding to formation of large crystallized regions of the phase change material portion 54.

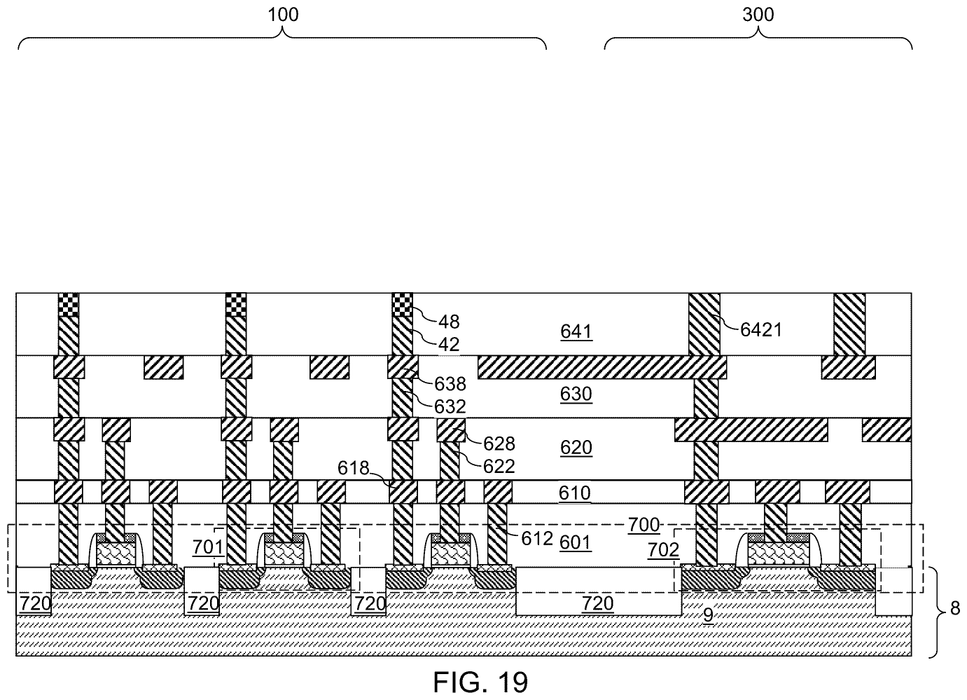

Referring to FIG. 19, a first alternative configuration of the embodiment structure is illustrated after formation of heater elements 48. In the first alternative configuration, the processing steps described with reference to FIG. 5 may be omitted. In this embodiment, each heater element 48 may have the same lateral dimension as a respective underlying bottom electrode 42. The sidewall of each heater element 48 may be vertically coincident with the sidewall of a respective underlying bottom electrode 42, i.e., may be located within a same vertical plane as the sidewall of the respective underlying bottom electrode 42.

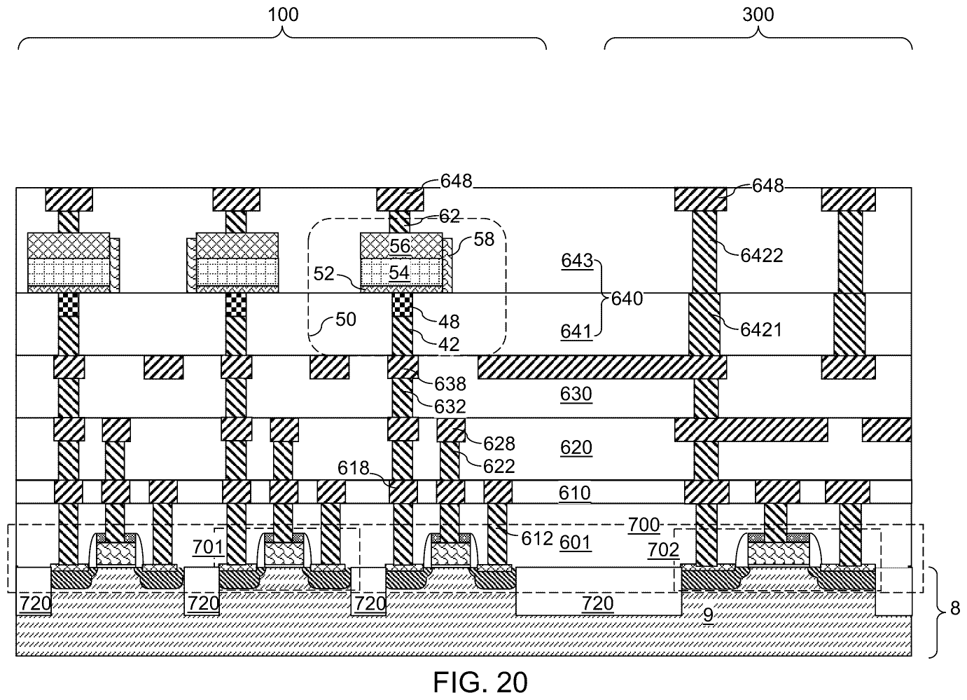

Referring to FIG. 20, the processing steps described with reference to FIGS. 7-17 may be performed on the first alternative configuration of the embodiment structure to provide an array of phase change memory cells 50.

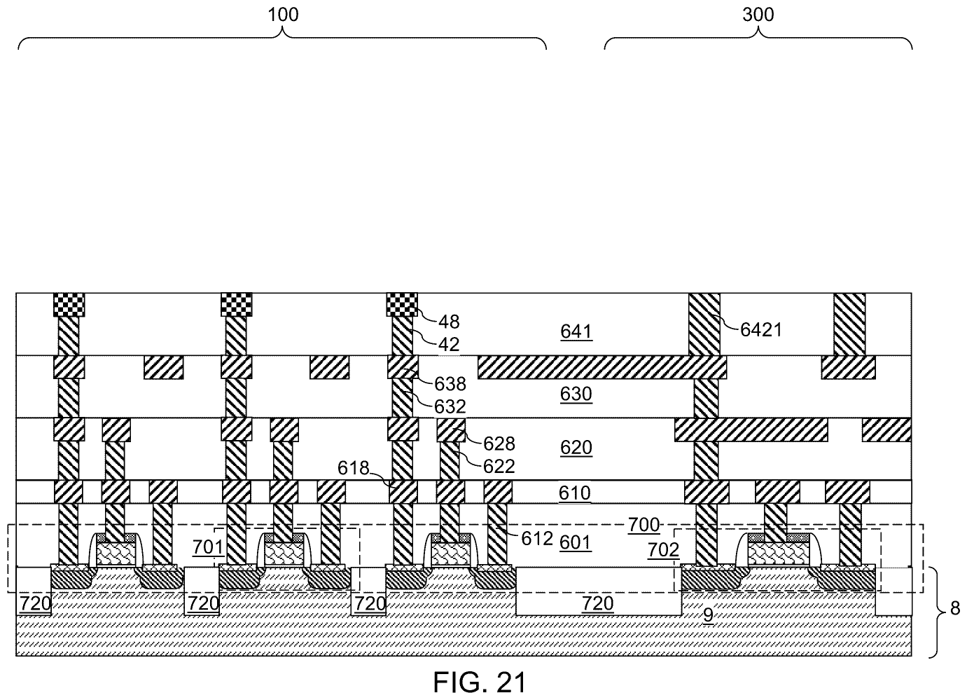

Referring to FIG. 21, the second alternative configuration of the embodiment structure is illustrated, which may be derived from the embodiment structure illustrated in FIG. 6 by using a chemical mechanical polishing process to remove portions of the metallic fill material that overlie the dielectric material layer embedding the bottom electrodes 42. In this embodiment, the entirety of the top surface of the dielectric material layer embedding the bottom electrodes 42 may be formed within a horizontal plane. In other words, the top surface of the dielectric material layer may be formed without any step. The top surfaces of the heater element 48 may be formed within the same horizontal plane as the top surface of the dielectric material layer that embeds the heater elements 48.

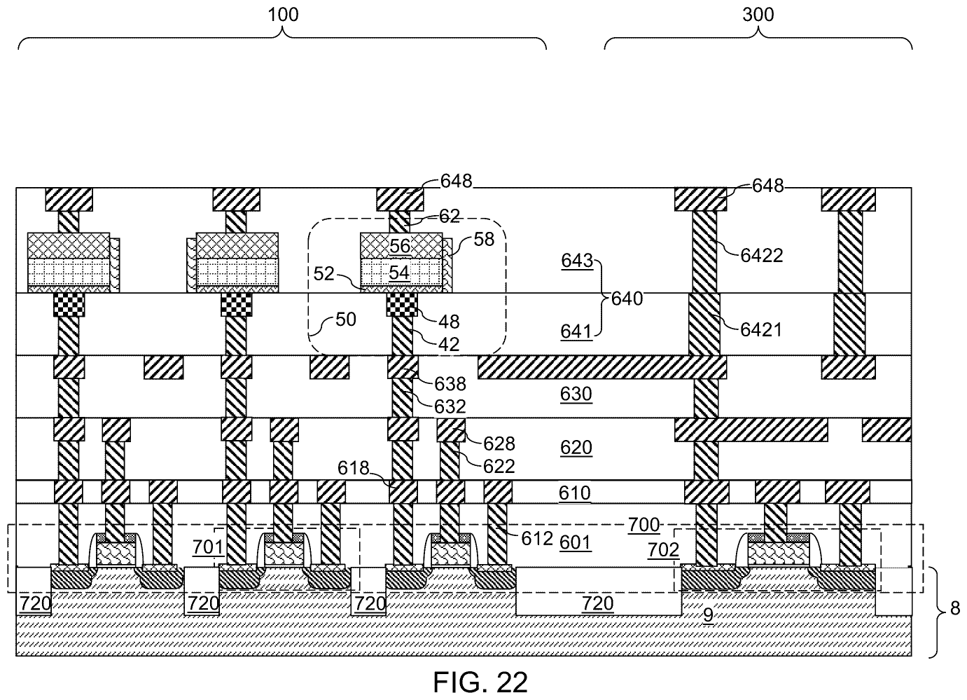

Referring to FIG. 22, the processing steps described with reference to FIGS. 7-17 may be performed on the second alternative configuration of the embodiment structure to provide an array of phase change memory cells 50.

Referring collectively to FIGS. 1-22 and according to various embodiments of the present disclosure, a device structure is provided, which comprises: a bottom electrode 42 and a heater element 48 embedded within a dielectric material layer; a layer stack (52, 54, 56) including a bottom liner 52, a phase change material portion 54 comprising a phase change material, and a top electrode 56; and at least one sidewall liner 58 located on at least one sidewall of the layer stack and comprising a material having an electrical conductivity that is higher than an electrical conductivity of an amorphous phase of the phase change material.

In one embodiment, the electrical conductivity of the amorphous phase of the phase change material is in a range from 1.0×10⁻⁸ S/cm to 1.0×10⁻³ S/cm; and the electrical conductivity of the sidewall liner 58 material is in a range from 1.0×10¹ S/cm to 1.0×10⁵ S/cm. In one embodiment, the bottom liner layer 52L comprises a material having an electrical conductivity that is at least 3 times the electrical conductivity of the sidewall liner material. In one embodiment, the device structure comprises an encapsulation dielectric layer 643 in contact with at least one sidewall of the layer stack, an outer sidewall of each of the at least one sidewall liner 58, and a top surface of the layer stack (52, 54, 56).

According to another aspect of the present disclosure, a device structure is provided, which comprises: a programming transistor 701 located on a substrate 8; a bottom electrode 42 and a heater element 48 embedded within a dielectric material layer, wherein the heater element 48 is electrically connected to an electrical node of the programming transistor 701; and a phase change memory cell 50 comprising a layer stack including a bottom liner 52, a phase change material portion 54 comprising a phase change material, and a top electrode 56, and further comprising at least one sidewall liner 58 located on at least one sidewall of the layer stack, wherein the programming transistor 701 is configured to program the phase change memory cell 50 into at least three different resistive states by applying at least three different programming pulse patterns to the heater element 48.

In one embodiment, the at least three different resistive states comprises: a high resistance state in which at least 99% of an entire volume of the phase change material portion 54 is in an amorphous phase; a low resistance state in which at least 99% of the entire volume of the phase change material portion 54 is in a polycrystalline phase; and a first intermediate state in which the phase change material portion 54 comprises a first volume having the amorphous phase and a second volume having the crystalline phase, the first volume is not in direct contact with the at least one sidewall liner 58, and having a higher resistance than the low resistance state. In one embodiment, the at least three different resistive states further comprise a second intermediate state containing an amorphous volume having the amorphous phase and contacting the bottom liner 52 and the at least one sidewall liner 58 and not contacting the top electrode 56; and the programming transistor 701 is configured to apply at least four different programming pulse patterns to the heater element 48.

In one embodiment, the bottom liner 52 comprises a first metallic nitride material; and the at least one sidewall liner 58 comprises a second metallic nitride material having an electrical conductivity that is less than ⅓ of an electrical conductivity of the first metallic nitride material.

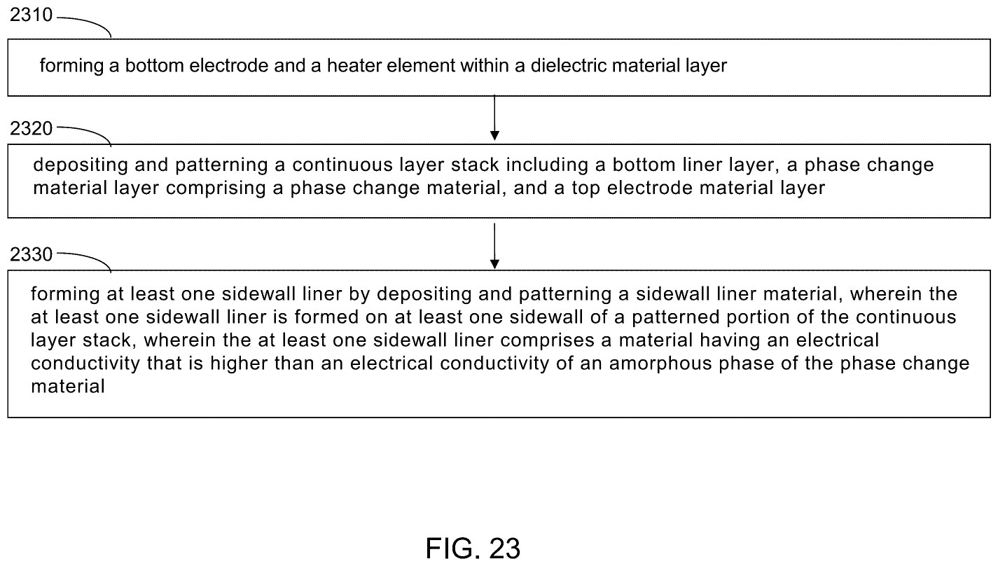

Referring to FIG. 23, a flowchart illustrates general processing steps for manufacturing a device structure.

Referring to step 2310 and FIGS. 1-6, a bottom electrode 42 and a heater element 48 may be formed within a dielectric material layer (which may be, but does not need to be, a lower fourth interconnect-level dielectric material layer 641).

Referring to step 2320 and FIGS. 7-16, a continuous layer stack (52L, 54L, 56L) including a bottom liner layer 52L, a phase change material layer 54L comprising a phase change material, and a top electrode material layer 56L may be deposited and patterned.

Referring to step 2330 and FIGS. 9-16, at least one sidewall liner 58 may be formed by depositing and patterning a sidewall liner 58 material. The at least one sidewall liner 58 is formed on at least one sidewall of a patterned portion of the continuous layer stack (52L, 54L, 56L). The at least one sidewall liner 58 comprises a material having an electrical conductivity that is higher than an electrical conductivity of an amorphous phase of the phase change material.

Within each phase change memory cell, the bottom liner 52 and the sidewall liner 58 are used to set the resistance levels of high resistance states of the phase change memory cell. The combination of the bottom liner 52 and the sidewall liner 58 suppresses the effect of resistance drift of the phase change material portion 54, reduces the power consumption of the phase change memory cell, reduces the error rate during operation of the phase change memory cell, and enables reduction of the cell size for the phase change memory cell. Generally, the thickness of the bottom liner 52 and the thickness of the sidewall liner 58 may be optimized to enable a wide variation in the resistance of various resistive states of the phase change memory cell, and to facilitate efficient multi-level cell (MLC) operation, i.e., a cell operation in which the cell is programmed to three or more resistive states. Thus, a large programming window may be provided for use of phase change memory cells 50 for an MLC operation.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a bottom electrode and a heater element within a dielectric material layer;
depositing and patterning a continuous layer stack including a bottom liner layer, a phase change material layer comprising a phase change material, and a top electrode material layer; and
forming at least one sidewall liner by depositing and patterning a sidewall liner material, wherein the at least one sidewall liner is formed on at least one sidewall of a patterned portion of the continuous layer stack, wherein the at least one sidewall liner comprises a material having an electrical conductivity that is higher than an electrical conductivity of an amorphous phase of the phase change material.

2. The method of claim 1, wherein the at least one sidewall liner is formed by:
conformally depositing a metallic nitride material layer;
reducing electrical conductivity of the metallic nitride material layer by incorporating carbon atoms or nitrogen atoms into the metallic nitride material layer; and
patterning the metallic nitride material layer after incorporating the carbon atoms or the nitrogen atoms therein.

3. The method of claim 2, wherein the carbon atoms or the nitrogen atoms are incorporated into the metallic nitride material layer at an atomic concentration such that the electrical conductivity of the metallic nitride material layer after incorporation of the carbon atoms or the nitrogen atoms is less than ⅓ of the electrical conductivity of the metallic nitride material layer prior to the incorporation of the carbon atoms or the nitrogen atoms.

4. The method of claim 1, wherein:
a combination of the patterned portion of the continuous layer stack and the at least one sidewall liner comprises a phase change memory cell;
the method further comprises forming a programming transistor on a substrate, and forming metal interconnect structures embedded within interconnect-level dielectric material layers over the programming transistor;
the heater element is electrically connected to an electrical node of the programming transistor; and
the programming transistor is configured to program the phase change memory cell into at least three different resistive states.

5. The method of claim 1, further comprising:
performing a first patterning process that patterns the continuous layer stack, wherein a remaining portion of the continuous layer stack comprises an in-process layer stack including an in-process bottom liner, an in-process phase change material portion, and an in-process top electrode; and
performing a second patterning process that patterns the in-process layer stack into multiple patterned portions, wherein said patterned portion of the continuous layer stack comprises one of the multiple patterned portions.

6. The method of claim 5, wherein:
the in-process layer stack comprises first sidewalls that laterally extend along a first horizontal direction and second sidewalls that laterally extend along a second horizontal direction;
the second patterning process removes unmasked portions of the in-process layer stack uses masking material portions that laterally extend along the second horizontal direction and laterally spaced apart from one another along the first horizontal direction; and
the multiple patterned portions comprise at least one row of patterned portions arranged along the first horizontal direction.

7. The method of claim 5, further comprising forming an in-process sidewall liner around the in-process layer stack by conformally depositing and anisotropically etching a layer of the sidewall liner material, wherein the second patterning process patterns the in-process sidewall liner into multiple portions comprising said at least one sidewall liner.

8. The method of claim 7, wherein the at least one sidewall liner consists of a single sidewall liner that is formed directly on a sidewall of said patterned portion of the continuous layer stack.

9. The method of claim 7, wherein the at least one sidewall liner comprises two sidewall liners that are formed on a pair of sidewalls of said patterned portion of the continuous layer stack that are parallel to each other.

10. The method of claim 7, wherein the at least one sidewall liner consists of a single sidewall liner that is formed directly on three sidewalls of said patterned portion of the continuous layer stack.

11. The method of claim 7, wherein the at least one sidewall liner has an annular configuration and is formed directly on each sidewall of said patterned portion of the continuous layer stack.

12. The method of claim 1, further comprising depositing an encapsulation dielectric layer directly on at least one sidewall of said patterned portion of the continuous layer stack and directly on an outer sidewall of each of the at least one sidewall liner and directly on a top surface of said patterned portion of the continuous layer stack.

13. A device structure comprising:
a bottom electrode and a heater element formed within a dielectric material layer;
a layer stack including a bottom liner layer, a phase change material portion comprising a phase change material, and a top electrode; and
at least one sidewall liner located on at least one sidewall of the layer stack and comprising a material having an electrical conductivity that is higher than an electrical conductivity of an amorphous phase of the phase change material.

14. The device structure of claim 13, wherein:
the electrical conductivity of the amorphous phase of the phase change material is in a range from 1.0×10⁻⁸ S/cm to 1.0×10⁻³ S/cm; and
the electrical conductivity of the at least one sidewall liner material is in a range from 1.0×10¹ S/cm to 1.0×10⁵ S/cm.

15. The device structure of claim 13, wherein the bottom liner layer comprises a material having an electrical conductivity that is at least 3 times the electrical conductivity of the at least one sidewall liner material.

16. The device structure of claim 13, further comprising an encapsulation dielectric layer in contact with at least one sidewall of the layer stack, an outer sidewall of each of the at least one sidewall liner, and a top surface of the layer stack.

17. A device structure comprising:
a programming transistor located on a substrate;
a bottom electrode and a heater element formed within a dielectric material layer, wherein the heater element is electrically connected to an electrical node of the programming transistor; and
a phase change memory cell comprising a layer stack including a bottom liner, a phase change material portion comprising a phase change material, and a top electrode, and further comprising at least one sidewall liner located on at least one sidewall of the layer stack,
wherein the programming transistor is configured to program the phase change memory cell into at least three different resistive states by applying at least three different programming pulse patterns to the heater element.

18. The device structure of claim 17, wherein the at least three different resistive states comprises:
a high resistance state in which at least 99% of an entire volume of the phase change material portion is in an amorphous phase;
a low resistance state in which at least 99% of the entire volume of the phase change material portion is in a polycrystalline phase; and
a first intermediate state having a higher resistance than the low resistance state, wherein the phase change material portion comprises a first volume having the amorphous phase and a second volume having a crystalline phase, and the first volume is not in direct contact with the at least one sidewall liner.

19. The device structure of claim 18, wherein:
the at least three different resistive states further comprise a second intermediate state containing an amorphous volume having the amorphous phase and contacting the bottom liner and the at least one sidewall liner and not contacting the top electrode; and
the programming transistor is configured to apply at least four different programming pulse patterns to the heater element.

20. The device structure of claim 17, wherein:
the bottom liner comprises a first metallic nitride material; and
the at least one sidewall liner comprises a second metallic nitride material having an electrical conductivity that is less than ⅓ of an electrical conductivity of the first metallic nitride material.
